(19) United States
(12) Patent Application Publication
(10) Pub. No.: US 2026/0110747 A1
(43) Pub. Date: Apr. 23, 2026

(54) Method for intuitive quantification of battery discharge balancing quality and battery management system using the same

(71) Applicant: CYBER POWER SYSTEMS, INC., TAIPEI CITY (TW)

(72) Inventors: HUNG-HUI LEE, TAIPEI CITY (TW); TA-PENG CHEN, TAIPEI CITY (TW); HUNG-CHUN CHIEN, TAIPEI CITY (TW)

(21) Appl. No.: 18/967,978

(22) Filed: Dec. 4, 2024

(30) Foreign Application Priority Data
Oct. 22, 2024 (CN) 202411476337X

(51) Int. Cl. G01R 31/385; G01R 31/36; H02J 7/00

(52) U.S. Cl. CPC G01R 31/385; G01R 31/3648; H02J 7/40; H02J 7/52; H02J 7/80

(57) ABSTRACT

A method for intuitive quantification of battery discharge balancing quality and a battery management system using the same are provided. The method comprises the following steps: calculating a battery discharge balancing index (B_DQ); and determining whether the number of battery strings is 1; if not, calculating a string discharge balancing index (S_DQ); if so, assigning a value of 100% to the string discharge balancing index (S_DQ).

### BACKGROUND OF THE INVENTION

### Field of the Invention

The present invention relates to the technical field of battery charging and discharging, and in particular to a method for intuitive quantification of battery discharge balancing quality and a battery management system using the same.

### Description of Related Art

Uninterruptible power system (UPS) is used to provide backup power to required equipment when AC mains fails, thereby ensuring that the equipment can still operate normally at this time. Generally speaking, uninterruptible power systems use battery systems to store backup power. The battery system generally consists of multiple battery strings connected in parallel, and each battery string consists of multiple batteries connected in series.

In order to verify the reliability of the uninterruptible power system, a discharge test is generally performed on the battery system to determine whether there is a long-term failure risk in the entire battery system. Once it is determined that there is a risk of long-term failure, it indicates that under the current conditions, the batteries of the battery system will face the risk of aging or even failure relatively quickly. During the discharge test, the battery management system (BMS) in the uninterruptible power system is typically used to measure the discharge current of each battery string and the voltage of each battery, so as to provide a series of measured current values and a series of measured voltage values for management personnel to analyze and interpret. This indicates that, in addition to requiring extensive expertise in battery systems, management personnel must also spend a significant amount of time to accomplish this.

### SUMMARY OF THE INVENTION

An object of the present invention is to provide a method for intuitive quantification of battery discharge balancing quality, which allows management personnel to quickly determine whether the entire battery system has a long-term failure risk, and they can do so without extensive expertise in battery systems.

Another object of the present invention is to provide a battery management system using the aforementioned method.

To achieve the above object, the present invention provides a method for intuitive quantification of battery discharge balancing quality, which is applicable to at least one battery string, wherein each battery string consists of m batteries connected in series, and m is a natural number. The method comprises the following steps: calculating a battery discharge balancing index (B_DQ); and determining whether the number of battery strings is 1; when the number of battery strings is not 1, calculating a string discharge balancing index (S_DQ); and when the number of battery strings is 1, assigning a value of 100% to the string discharge balancing index (S_DQ). The steps for calculating the battery discharge balancing index (B_DQ) comprise: measuring the discharge energy of each battery in each of n time slots to obtain n measured values of each battery, where n is a natural number; calculating an average discharge energy of the batteries in the same battery string in each time slot, and accordingly calculating at least one degree of deviation in discharge energy of the batteries in the same battery string relative to the average discharge energy; and calculating an average degree of deviation in discharge energy of the batteries in all time slots based on the calculated degrees of deviations in discharge energies, and serving the calculated average degree as the battery discharge balancing index (B_DQ).

To achieve the above another object, the present invention provides a battery management system, which comprises at least one battery string and a control circuit, wherein each battery string consists of m batteries connected in series, and m is a natural number. The control circuit is electrically coupled to two terminals of each battery. The control circuit is used to calculate a battery discharge balancing index (B_DQ) and to determine whether the number of battery strings is 1. The control circuit calculates a string discharge balancing index (S_DQ) when the number of the battery strings is not 1, and assigns a value of 100% to the string discharge balancing index (S_DQ) when the number of the battery strings is 1. The steps of the control circuit for calculating the battery discharge balancing index (B_DQ) comprise: measuring the discharge energy of each battery in each of n time slots to obtain n measured values of each battery, where n is a natural number; calculating an average discharge energy of the batteries in the same battery string in each time slot, and accordingly calculating at least one degree of deviation in discharge energy of the batteries in the same battery string relative to the average discharge energy; and calculating an average degree of deviation in discharge energy of the batteries in all time slots based on the calculated degrees of deviations in discharge energies, and serving the calculated average degree as the battery discharge balancing index (B_DQ).

In order to make the above objects, technical features and gains after actual implementation more obvious and easy to understand, in the following, the preferred embodiments will be described with reference to the corresponding drawings and will be described in more detail.

### BRIEF DESCRIPTION OF THE DRAWINGS

Other features and advantages of the present invention will become apparent in the following detailed description of the preferred embodiments with reference to the accompanying drawings, of which:

FIG. 1 shows a battery management system according to an embodiment of the present invention.

FIG. 2 is a flow chart of a method for intuitive quantification of battery discharge balancing quality according to an embodiment of the present invention.

FIG. 3 is a flow chart of a method for calculating the battery discharge balancing index (B_DQ) according to an embodiment of the present invention.

FIG. 4 is a flow chart of a method for calculating the string discharge balancing index (S_DQ) according to an embodiment of the present invention.

### DESCRIPTION OF EMBODIMENTS

The characteristics, contents, advantages and achieved effects of the present disclosure will become more fully understood from the detailed description given herein below and the accompanying drawings which are given by way of illustration only, and thus are not limitative of the present disclosure.

As required, detailed embodiments are disclosed herein. It must be understood that the disclosed embodiments are merely exemplary of and may be embodied in various and alternative forms, and combinations thereof. As used herein, the word “exemplary” is used expansively to refer to embodiments that serve as illustrations, specimens, models, or patterns. The figures are not necessarily to scale and some features may be exaggerated or minimized to show details of particular components. In other instances, well-known components, systems, materials, or methods that are known to those having ordinary skill in the art have not been described in detail in order to avoid obscuring the present disclosure. Therefore, specific structural and functional details disclosed herein are not to be interpreted as limiting, but merely as a basis for the claims and as a representative basis for teaching one skilled in the art.

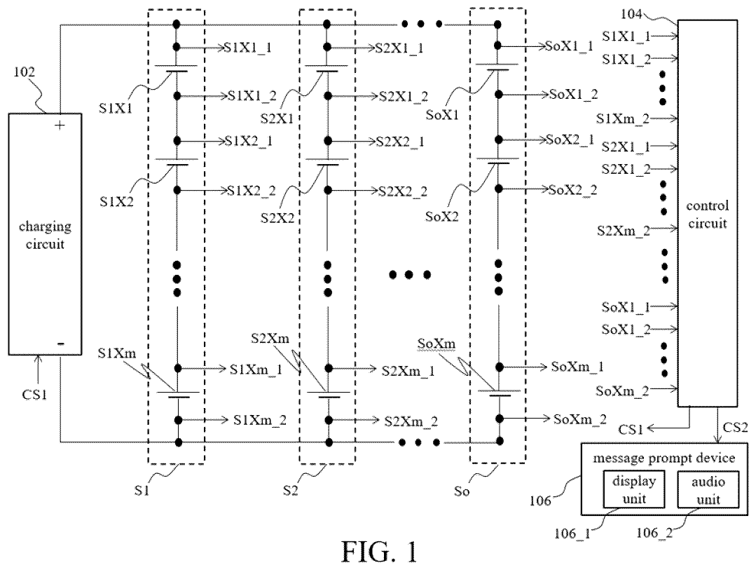

FIG. 1 shows a battery management system according to an embodiment of the present invention. Referring to FIG. 1, the battery management system comprises a battery system comprising battery strings S1 to So, a control circuit 104 and a message prompt device 106, where o is a natural number. The battery strings are connected in parallel, and each battery string consists of m batteries connected in series, where m is also a natural number. Taking the battery string S1 as an example, it consists of batteries S1X1 to S1Xm connected in series. Taking the battery string S2 as another example, it consists of batteries S2X1 to S2Xm connected in series. In addition, the control circuit 104 is electrically coupled to two terminals of each battery to measure the voltage of each battery and to measure the current of each battery string. Taking the battery S1X1 as an example, its two terminals are represented as S1X1_1 and S1X1_2 respectively. Taking the battery S2X2 as another example, its two terminals are represented as S2X2_1 and S2X2_2 respectively. As can be seen from the above, in this embodiment, the control circuit 104 has the functions of voltage sensing and current sensing. Certainly, in other embodiments, the voltage sensing function and the current sensing function can be implemented using an external circuit independent of the control circuit 104. In addition, a charging circuit 102 is also shown in FIG. 1. The charging circuit 102 is electrically coupled to two terminals of each battery string to charge each battery string. The control circuit 104 is also electrically coupled to the charging circuit 102 and the message prompt device 106, and controls the operations of the two using control signals CS1 and CS2 respectively.

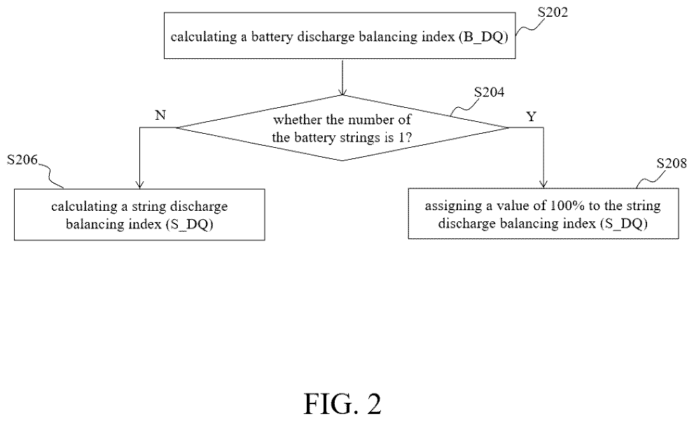

FIG. 2 is a flow chart of a method for intuitive quantification of battery discharge balancing quality according to an embodiment of the present invention. Please refer to FIGS. 2 and 1. First, the control circuit 104 calculates a battery discharge balancing index (B_DQ), as shown in step S202. The calculation method will be described in detail later. Next, the control circuit 104 determines whether the number of battery strings is 1, as shown in step S204. When the number of battery strings is not 1, the control circuit 104 calculates a string discharge balancing index (S_DQ), as shown in step S206. The calculation method will be described in detail later. On the other hand, when the number of battery strings is 1, the control circuit 104 assigns a value of 100% to the string discharge balancing index (S_DQ), as shown in step S208. The obtained values of the battery discharge balancing index (B_DQ) and the string discharge balancing index (S_DQ) can indicate whether there is a risk of long-term failure in the entire battery system (detailed later).

The following will illustrate the four calculation methods of the battery discharge balancing index (B_DQ) and the four calculation methods of the string discharge balancing index (S_DQ) with reference to FIGS. 1, 3, 4 and each table. It should be noted that these calculation methods are only used as examples and are not intended to limit the present invention. In addition, for the convenience of explanation, the following descriptions will assume that the battery management system shown in FIG. 1 only has two battery strings, S1 and S2, and each battery string consists of three batteries (labeled X1 to X3) connected in series.

### The First Calculation Method of Battery Discharge Balancing Index (B_DQ):

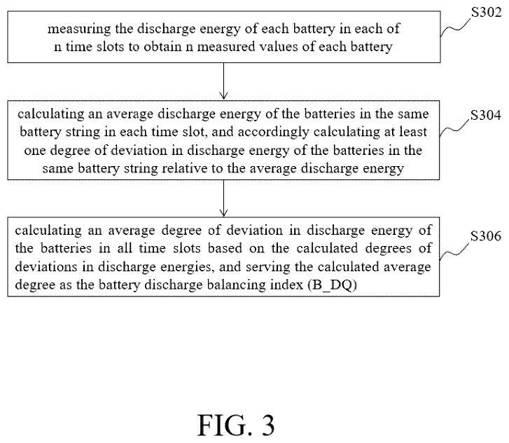

FIG. 3 is a flow chart of a method for calculating the battery discharge balancing index (B_DQ) according to an embodiment of the present invention. In addition, the following Table 1 and Table 2 are used to illustrate the first calculation method of the battery discharge balancing index (B_DQ). Please refer to FIG. 3, FIG. 1, Table 1 and Table 2. First, the control circuit 104 measures the discharge energy of each battery in each of n time slots to obtain n measured values of each battery (where n is a natural number), as shown in step S302. In this embodiment, n is 9. The measured values of the discharge energies of the batteries S1X1 to S1X3 in the battery string S1 are shown in Table 1, and the measured values of the discharge energies of the batteries S2X1 to S2X3 in the battery string S2 are shown in Table 2. In Tables 1 and 2, the unit of discharge energy is the product of watts (W) and hours (Hr), where watts is the product of the battery voltage and the discharge current of the battery string.

TABLE 1

| | | | | | degree of deviation in | | |
|---|---|---|---|---|---|---|---|
| | discharge energy (W × Hr) | | | | discharge energy (%) | | |
| time slot | S1X1 | S1X2 | S1X3 | BE_avg | S1X1 | S1X2 | S1X3 |
| T1 (9:53 to 10:03) | 22.9391 | 22.9355 | 22.9147 | 22.9298 | 0.04% | 0.03% | −0.07% |
| T2 (10:03 to 10:13) | 24.9179 | 24.9288 | 24.9085 | 24.9184 | 0.00% | 0.04% | −0.04% |
| T3 (10:13 to 10:24) | 22.221 | 22.2372 | 22.2225 | 22.2269 | −0.03% | 0.05% | −0.02% |
| T4 (10:24 to 10:34) | 22.8158 | 22.8322 | 22.8267 | 22.8249 | −0.04% | 0.03% | 0.01% |
| T5 (10:34 to 10:44) | 22.8966 | 22.9212 | 22.9212 | 22.913 | −0.07% | 0.04% | 0.04% |
| T6 (10:44 to 10:54) | 26.6955 | 26.7133 | 26.7571 | 26.7219 | −0.10% | −0.03% | 0.13% |
| T7 (10:54 to 11:04) | 25.2504 | 24.9667 | 25.3866 | 25.2012 | 0.20% | −0.93% | 0.74% |
| T8 (11:04 to 11:14) | 13.8313 | 11.8728 | 13.9469 | 13.217 | 4.65% | −10.17% | 5.52% |
| T9 (11:14 to 11:24) | 9.28798 | 7.75202 | 9.45678 | 8.83226 | 5.16% | −12.23% | 7.07% |

TABLE 2

| | | | | | degree of deviation in | | |
|---|---|---|---|---|---|---|---|
| | discharge energy (W × Hr) | | | | discharge energy (%) | | |
| time slot | S2X1 | S2X2 | S2X3 | BE_avg | S2X1 | S2X2 | S2X3 |
| T1 (9:53 to 10:03) | 20.589 | 20.3885 | 20.6106 | 20.5294 | 0.29% | −0.69% | 0.40% |
| T2 (10:03 to 10:13) | 22.4893 | 22.1641 | 22.5216 | 22.3917 | 0.44% | −1.02% | 0.58% |
| T3 (10:13 to 10:24) | 20.3582 | 19.9772 | 20.389 | 20.2415 | 0.58% | −1.31% | 0.73% |
| T4 (10:24 to 10:34) | 20.8582 | 20.3475 | 20.8961 | 20.7006 | 0.76% | −1.71% | 0.94% |
| T5 (10:34 to 10:44) | 19.6696 | 18.9174 | 19.7043 | 19.4304 | 1.23% | −2.64% | 1.41% |
| T6 (10:44 to 10:54) | 15.9315 | 14.4136 | 15.9627 | 15.4359 | 3.21% | −6.62% | 3.41% |
| T7 (10:54 to 11:04) | 17.691 | 14.7504 | 17.7258 | 16.7224 | 5.79% | −11.79% | 6.00% |
| T8 (11:04 to 11:14) | 30.4467 | 24.0023 | 30.5177 | 28.3222 | 7.50% | −15.25% | 7.75% |
| T9 (11:14 to 11:24) | 17.7288 | 13.667 | 17.7799 | 16.3919 | 8.16% | −16.62% | 8.47% |

Next, the control circuit 104 calculates an average discharge energy of the batteries in the same battery string in each time slot based on the following equation (1), as shown in step S304:

$$BE\_avg ( Sk , Tj ) = \frac{1}{m} {\sum }_{i = 1}^{m} BE ( SkXi , Tj ) \qquad ( 1 )$$

where Sk in (SkXi, Tj) represents the kth battery string, Xi represents the ith battery, Tj represents the jth time slot, BE(SkXi,Tj) represents the discharge energy of the battery SkXi in the jth time slot, where the value of k is 1 to o, the value of i is 1 to m, and the value of j is 1 to n. The calculated values of the average discharge energies are shown in Tables 1 and 2.

After calculating an average discharge energy of the batteries in the same battery string in each time slot, the control circuit 104 accordingly calculates at least one degree of deviation in discharge energy of the batteries in the same battery string relative to the average discharge energy (as shown in step S304). In this embodiment, the control circuit 104 calculates the said at least one degree of deviation in discharge energy of the batteries in the same battery string relative to the average discharge energy based on the following equation (2):

$$BDq ( Xi , Tj ) = \frac{BE ( SkXi , Tj ) - BE\_avg ( Sk , Tj )}{BE\_avg ( Sk , Tj )} \qquad ( 2 )$$

The calculated degrees of deviations in discharge energies are shown in Tables 1 and 2.

Then, the control circuit 104 calculates an average degree of deviation in discharge energy of the batteries in all time slots based on the calculated degrees of deviations in discharge energies, and serves the calculated average degree as the battery discharge balancing index (B_DQ), as shown in step S306. In this embodiment, the control circuit 104 calculates the average degree of deviation in discharge energy based on the following equations (3) and (4):

$$BDQ ( Xi ) = 1 - \frac{1}{n} {\sum }_{j = 1}^{n} \vert BDq ( SkXi , Tj ) \vert \qquad ( 3 )$$

$$B\_DQ = \frac{1}{o * m} {\sum }_{k = 1}^{o} {\sum }_{i = 1}^{m} BDQ ( SkXi ) \qquad ( 4 )$$

Based on the above, substituting the calculated degrees of deviations in discharge energies of the battery S1X1 in Table 1 into equation (3) gives 98.86%; substituting the calculated degrees of deviations in discharge energies of the battery S1X2 in Table 1 into equation (3) gives 97.38%; and substituting the calculated degrees of deviations in discharge energies of the battery S1X3 in Table 1 into equation (3) gives 98.49%. Similarly, substituting the calculated degrees of deviations in discharge energies of the battery S2X1 in Table 2 into equation (3) gives 96.89%; substituting the calculated degrees of deviations in discharge energies of the battery S2X2 in Table 2 into equation (3) gives 93.59%; and substituting the calculated degrees of deviations in discharge energies of the battery S2X3 in Table 2 into equation (3) gives 96.7%. Then, substituting these six calculated results into equation (4) gives 97%. Therefore, in this embodiment, the value of the battery discharge balancing index (B_DQ) is 97%.

### The First Calculation Method of String Discharge Balancing Index (S_DQ):

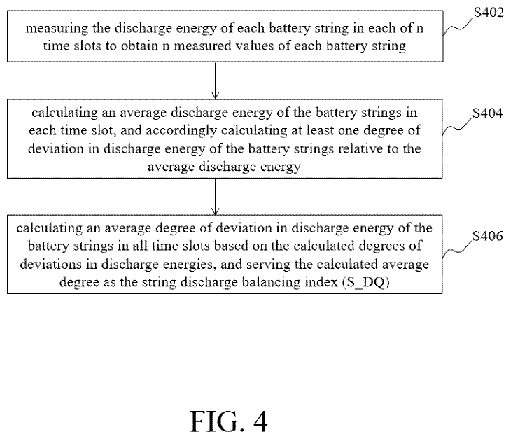

FIG. 4 is a flow chart of a method for calculating the string discharge balancing index (S_DQ) according to an embodiment of the present invention. In addition, the following Table 3 is used to illustrate the first calculation method of the string discharge balancing index (S_DQ). Please refer to FIG. 4, FIG. 1 and Table 3. First, the control circuit 104 measures the discharge energy of each battery string in each of n time slots to obtain n measured values of each battery string, as shown in step S402. The measured values of the discharge energies of the battery strings S1 and S2 are shown in Table 3. In Table 3, the unit of discharge energy is the product of watts (W) and hours (Hr), where watts is the product of the string voltage and the discharge current of the battery string.

TABLE 3

| | | | | degree of deviation in | |
|---|---|---|---|---|---|
| | discharge energy (W × Hr) | | | discharge energy (%) | |
| time slot | S1 | S2 | SE_avg | S1 | S2 |
| T1 (9:53 to 10:03) | 68.7893 | 61.5881 | 65.1887 | 5.52% | −5.52% |
| T2 (10:03 to 10:13) | 74.7552 | 67.175 | 70.9651 | 5.34% | −5.34% |
| T3 (10:13 to 10:24) | 66.6807 | 60.7244 | 63.7025 | 4.68% | −4.68% |
| T4 (10:24 to 10:34) | 68.4746 | 62.1018 | 65.2882 | 4.88% | −4.88% |
| T5 (10:34 to 10:44) | 68.739 | 58.2913 | 63.5152 | 8.22% | −8.22% |
| T6 (10:44 to 10:54) | 80.1658 | 46.3077 | 63.2368 | 26.77% | −26.77% |
| T7 (10:54 to 11:04) | 75.6037 | 50.1671 | 62.8854 | 20.22% | −20.22% |
| T8 (11:04 to 11:14) | 39.651 | 84.9667 | 62.3089 | −36.36% | 36.36% |
| T9 (11:14 to 11:24) | 26.4968 | 49.1757 | 37.8363 | −29.97% | 29.97% |

Next, the control circuit 104 calculates an average discharge energy of the battery strings in each time slot based on the following equations (14) and (15), as shown in step S404:

$$SE ( Sk , Tj ) = {\sum }_{i = 1}^{m} BE ( SkXi , Tj ) \qquad ( 14 )$$

$$SE\_avg ( Tj ) = \frac{1}{o} {\sum }_{k = 1}^{o} SE ( Sk , Tj ) \qquad ( 15 )$$

The calculated values of the average discharge energies are shown in Table 3.

After calculating an average discharge energy of the battery strings in each time slot, the control circuit 104 accordingly calculates at least one degree of deviation in discharge energy of the battery strings relative to the average discharge energy (as shown in step S404). In this embodiment, the control circuit 104 calculates the said at least one degree of deviation in discharge energy of the battery strings relative to the average discharge energy based on the following equation (16):

$$SDq ( Sk , Tj ) = \frac{SE ( Sk , Tj ) - SE\_avg ( Tj )}{SE\_avg ( Tj )} \qquad ( 16 )$$

The calculated degrees of deviations in discharge energies are shown in Table 3.

Then, the control circuit 104 calculates an average degree of deviation in discharge energy of the battery strings in all time slots based on the calculated degrees of deviations in discharge energies, and serves the calculated average degree as the string discharge balancing index (S_DQ), as shown in step S406. In this embodiment, the control circuit 104 calculates the average degree of deviation in discharge energy of the battery strings based on the following equations (17) and (18):

$$SDQ ( Sk ) = 1 - \frac{1}{n} {\sum }_{j = 1}^{n} \vert SDq ( Sk , Tj ) \vert \qquad ( 17 )$$

$$S\_DQ = \frac{1}{o} {\sum }_{k = 1}^{o} SDQ ( Sk ) \qquad ( 18 )$$

Based on the above, substituting the calculated degrees of deviations in discharge energies of the battery string S1 in Table 3 into equation (17) gives 84.23%; substituting the calculated degrees of deviations in discharge energies of the battery string S2 in Table 3 into equation (17) gives 84.23%. Then, substituting these two calculated results into equation (18) gives 84.23%. Therefore, in this embodiment, the value of the string discharge balancing index (S_DQ) is 84.23%.

The following Table 4 is used to enumerate and explain the practical application of the battery discharge balancing index (B_DQ) and the string discharge balancing index (S_DQ). In this embodiment, the threshold of the battery discharge balance indicator (B_DQ) is 99%, and the threshold of the battery string discharge balance indicator (S_DQ) is 95%. If the values of the battery discharge balancing index (B_DQ) and the string discharge balancing index (S_DQ) are both higher than the corresponding thresholds, it indicates that the condition is good. If only the value of the string discharge balancing index (S_DQ) is lower than its threshold, it indicates that there is an abnormal

TABLE 4

| B_DQ | S_DQ | condition description |
|---|---|---|
| 99.68% | 96.32% | in good condition |
| 99.59% | 86.07% | abnormal wiring |
| 97.17% | 84.58% | There is an aged or low-capacity battery |
| 97.13% | 85.52% | There is an aged or low-capacity battery |
| 98.18% | 85.63% | There is an aged or low-capacity battery |

wiring condition. The reason may be poor contact or inconsistent wiring resistance. If the values of the battery discharge balancing index (B_DQ) and the string discharge balancing index (S_DQ) are both lower than the corresponding thresholds, it indicates that there is an aging or low-capacity battery. A low capacity battery may be caused by not being properly charged.

It is worth mentioning that under different battery system installation environments, the thresholds of the battery discharge balancing index (B_DQ) and the string discharge balancing index (S_DQ) will also be different. Therefore, the thresholds of the battery discharge balancing index (B_DQ) and the string discharge balancing index (S_DQ) must be further evaluated based on the actual installation environment of the battery system. In addition, as shown in FIG. 2, when there is only one battery string, it is sufficient to assign the value of the string discharge balancing index (S_DQ) to be 100%. Certainly, the numerical values in Tables 1 to 4 are only for illustration and are not intended to limit the present invention.

Please refer to FIG. 1 again. Based on the above, after obtaining the values of the battery discharge balancing index (B_DQ) and the string discharge balancing index (S_DQ), the control circuit 104 can present the obtained two values by the message prompt device 106. In this embodiment, the message prompt device 106 comprises at least one of a display unit 106_1 or an audio unit 106_2, so as to present the obtained values of the battery discharge balancing index (B_DQ) and the string discharge balancing index (S_DQ) in at least one of visual or audio forms. The display unit 106_1 can be implemented by, for example, a Liquid-Crystal Display (LCD) or a seven-segment LED display, and the audio unit 106_2 can be implemented by, for example, a speaker or a buzzer. The display unit 106_1 can directly display the values of the battery discharge balancing index (B_DQ) and the string discharge balancing index (S_DQ). The speaker can directly send an audio message indicating the values of the battery discharge balancing index (B_DQ) and the string discharge balancing index (S_DQ). The buzzer, for example, can use a combination of long and short sounds to represent a corresponding value.

In addition, the control circuit 104 may also generate a prompt message based on the obtained values of the battery discharge balancing index (B_DQ) and the string discharge balancing index (S_DQ), and sends the prompt message through the message prompt device 106. Please refer to FIG. 1 and Table 4. For example, when the control circuit 104 determines that the obtained values of the battery discharge balancing index (B_DQ) and the string discharge balancing index (S_DQ) reflect a wiring abnormality in the battery system, then the control circuit 104 can generate a corresponding prompt message accordingly, and send the prompt message through at least one of the display unit 106_1 or the audio unit 106_2. In other words, the prompt message sent may be at least one of a visual message or an audio message.

As can be seen from the above, the present invention allows management personnel to quickly determine whether the entire battery system has a long-term failure risk, and management personnel can do so without extensive expertise in battery systems.

### The Second Calculation Method of Battery Discharge Balancing Index (B_DQ):

The following Table 5 and Table 6 are used to illustrate the second calculation method of the battery discharge balancing index (B_DQ). Please refer to FIG. 3, FIG. 1, Table 5 and Table 6.

TABLE 5

| | | | | | degree of deviation in | | |
|---|---|---|---|---|---|---|---|
| | discharge energy (W × Hr) | | | | discharge energy (%) | | |
| time slot | S1X1 | S1X2 | S1X3 | BE_avg | S1X1 | S1X2 | S1X3 |
| T1 (9:53 to 10:03) | 22.9391 | 22.9355 | 22.9147 | 22.9298 | 100.04% | 100.03% | 99.93% |
| T2 (10:03 to 10:13) | 24.9179 | 24.9288 | 24.9085 | 24.9184 | 100.00% | 100.04% | 99.96% |
| T3 (10:13 to 10:24) | 22.221 | 22.2372 | 22.2225 | 22.2269 | 99.97% | 100.05% | 99.98% |
| T4 (10:24 to 10:34) | 22.8158 | 22.8322 | 22.8267 | 22.8249 | 99.96% | 100.03% | 100.01% |
| T5 (10:34 to 10:44) | 22.8966 | 22.9212 | 22.9212 | 22.913 | 99.93% | 100.04% | 100.04% |
| T6 (10:44 to 10:54) | 26.6955 | 26.7133 | 26.7571 | 26.7219 | 99.9% | 99.97% | 100.13% |
| T7 (10:54 to 11:04) | 25.2504 | 24.9667 | 25.3866 | 25.2012 | 99.8% | 99.07% | 100.74% |
| T8 (11:04 to 11:14) | 13.8313 | 11.8728 | 13.9469 | 13.217 | 104.65% | 89.83% | 105.52% |
| T9 (11:14 to 11:24) | 9.28798 | 7.75202 | 9.45678 | 8.83226 | 105.16% | 87.77% | 107.07% |

TABLE 6

| | | | | | degree of deviation in | | |
|---|---|---|---|---|---|---|---|
| | discharge energy (W × Hr) | | | | discharge energy (%) | | |
| time slot | S2X1 | S2X2 | S2X3 | BE_avg | S2X1 | S2X2 | S2X3 |
| T1 (9:53 to 10:03) | 20.589 | 20.3885 | 20.6106 | 20.5294 | 100.29% | 99.31% | 100.40% |
| T2 (10:03 to 10:13) | 22.4893 | 22.1641 | 22.5216 | 22.3917 | 100.44% | 98.98% | 100.58% |
| T3 (10:13 to 10:24) | 20.3582 | 19.9772 | 20.389 | 20.2415 | 100.58% | 98.69% | 100.73% |
| T4 (10:24 to 10:34) | 20.8582 | 20.3475 | 20.8961 | 20.7006 | 100.76% | 98.29% | 100.94% |
| T5 (10:34 to 10:44) | 19.6696 | 18.9174 | 19.7043 | 19.4304 | 101.23% | 97.36% | 101.41% |
| T6 (10:44 to 10:54) | 15.9315 | 14.4136 | 15.9627 | 15.4359 | 103.21% | 93.38% | 103.41% |
| T7 (10:54 to 11:04) | 17.691 | 14.7504 | 17.7258 | 16.7224 | 105.79% | 88.21% | 106.00% |
| T8 (11:04 to 11:14) | 30.4467 | 24.0023 | 30.5177 | 28.3222 | 107.50% | 84.75% | 107.75% |
| T9 (11:14 to 11:24) | 17.7288 | 13.667 | 17.7799 | 16.3919 | 108.16% | 83.38% | 108.47% |

First, the control circuit 104 measures the discharge energy of each battery in each of n time slots to obtain n measured values of each battery, as shown in step S302. In this embodiment, n is 9. The measured values of the discharge energies of the batteries S1X1 to S1X3 in the battery string S1 are shown in Table 5, and the measured values of the discharge energies of the batteries S2X1 to S2X3 in the battery string S2 are shown in Table 6. In Tables 5 and 6, the unit of discharge energy is the product of watts (W) and hours (Hr), where watts is the product of the battery voltage and the discharge current of the battery string.

Next, the control circuit 104 calculates an average discharge energy of the batteries in the same battery string in each time slot based on the following equation (1), as shown in step S304:

$$BE\_avg ( Sk , Tj ) = \frac{1}{m} {\sum }_{i = 1}^{m} BE ( SkXi , Tj ) \qquad ( 1 )$$

Since the content of equation (1) has been mentioned in the previous explanation, it will not be repeated here. The calculated values of the average discharge energies are shown in Tables 5 and 6.

After calculating an average discharge energy of the batteries in the same battery string in each time slot, the control circuit 104 accordingly calculates at least one degree of deviation in discharge energy of the batteries in the same battery string relative to the average discharge energy (as shown in step S304). In this embodiment, the control circuit 104 calculates the said at least one degree of deviation in discharge energy of the batteries in the same battery string relative to the average discharge energy based on the following equation (5):

$$BDq ( Xi , Tj ) = \frac{BE ( SkXi , Tj )}{BE\_avg ( Sk , Tj )} \qquad ( 5 )$$

The calculated degrees of deviations in discharge energies are shown in Tables 5 and 6.

Then, the control circuit 104 calculates an average degree of deviation in discharge energy of the batteries in all time slots based on the calculated degrees of deviations in discharge energies, and serves the calculated average degree as the battery discharge balancing index (B_DQ), as shown in step S306. In this embodiment, the control circuit 104 calculates the average degree of deviation in discharge energy based on the following equations (6) and (7):

$$BDQ ( Xi ) = 1 - \frac{1}{n} {\sum }_{j = 1}^{n} \vert BDq ( SkXi , Tj ) - 100 \% \vert \qquad ( 6 )$$

$$B\_DQ = \frac{1}{o * m} {\sum }_{k = 1}^{o} {\sum }_{i = 1}^{m} BDQ ( SkXi ) \qquad ( 7 )$$

Based on the above, substituting the calculated degrees of deviations in discharge energies of the battery S1X1 in Table 5 into equation (6) gives 98.86%; substituting the calculated degrees of deviations in discharge energies of the battery S1X2 in Table 5 into equation (6) gives 97.38%; and substituting the calculated degrees of deviations in discharge energies of the battery S1X3 in Table 5 into equation (6) gives 98.49%. Similarly, substituting the calculated degrees of deviations in discharge energies of the battery S2X1 in Table 6 into equation (6) gives 96.89%; substituting the calculated degrees of deviations in discharge energies of the battery S2X2 in Table 6 into equation (6) gives 93.59%; and substituting the calculated degrees of deviations in discharge energies of the battery S2X3 in Table 6 into equation (6) gives 96.70%. Then, substituting these six calculated results into equation (7) gives 97%. Therefore, in this embodiment, the value of the battery discharge balancing index (B_DQ) is 97%.

### The Second Calculation Method of String Discharge Balancing Index (S_DQ):

The following Table 7 is used to illustrate the second calculation method of the string discharge balancing index (S_DQ). Please refer to FIG. 4, FIG. 1 and Table 7. First, the control circuit

TABLE 7

| | | | | degree of deviation in | |
|---|---|---|---|---|---|
| | discharge energy (W × Hr) | | | discharge energy (%) | |
| time slot | S1 | S2 | SE_avg | S1 | S2 |
| T1 (9:53 to 10:03) | 68.7893 | 61.5881 | 65.1887 | 105.52% | 94.48% |
| T2 (10:03 to 10:13) | 74.7552 | 67.175 | 70.9651 | 105.34% | 94.66% |
| T3 (10:13 to 10:24) | 66.6807 | 60.7244 | 63.7025 | 104.68% | 95.32% |
| T4 (10:24 to 10:34) | 68.4746 | 62.1018 | 65.2882 | 104.88% | 95.12% |
| T5 (10:34 to 10:44) | 68.739 | 58.2913 | 63.5152 | 108.22% | 91.78% |
| T6 (10:44 to 10:54) | 80.1658 | 46.3077 | 63.2368 | 126.77% | 73.23% |
| T7 (10:54 to 11:04) | 75.6037 | 50.1671 | 62.8854 | 120.22% | 79.78% |
| T8 (11:04 to 11:14) | 39.651 | 84.9667 | 62.3089 | 63.64% | 136.36% |
| T9 (11:14 to 11:24) | 26.4968 | 49.1757 | 37.8363 | 70.03% | 129.97% |

104 measures the discharge energy of each battery string in each of n time slots to obtain n measured values of each battery string, as shown in step S402. The measured values of the discharge energies of the battery strings S1 and S2 are shown in Table 7. In Table 7, the unit of discharge energy is the product of watts (W) and hours (Hr), where watts is the product of the string voltage and the discharge current of the battery string.

Next, the control circuit 104 calculates an average discharge energy of the battery strings in each time slot based on the following equations (14) and (15), as shown in step S404:

$$SE ( Sk , Tj ) = {\sum }_{i = 1}^{m} BE ( SkXi , Tj ) \qquad ( 14 )$$

$$SE\_avg ( Tj ) = \frac{1}{o} {\sum }_{k = 1}^{o} SE ( Sk , Tj ) \qquad ( 15 )$$

The calculated values of the average discharge energies are shown in Table 7.

After calculating an average discharge energy of the battery strings in each time slot, the control circuit 104 accordingly calculates at least one degree of deviation in discharge energy of the battery strings relative to the average discharge energy (as shown in step S404). In this embodiment, the control circuit 104 calculates the said at least one degree of deviation in discharge energy of the battery strings relative to the average discharge energy based on the following equation (19):

$$SDq ( Sk , Tj ) = \frac{SE ( Sk , Tj )}{SE\_avg ( Tj )} \qquad ( 19 )$$

The calculated degrees of deviations in discharge energies are shown in Table 7.

Then, the control circuit 104 calculates an average degree of deviation in discharge energy of the battery strings in all time slots based on the calculated degrees of deviations in discharge energies, and serves the calculated average degree as the string discharge balancing index (S_DQ), as shown in step S406. In this embodiment, the control circuit 104 calculates the average degree of deviation in discharge energy of the battery strings based on the following equations (20) and (21):

$$SDQ ( Sk ) = 1 - \frac{1}{n} {\sum }_{j = 1}^{n} \vert SDq ( Sk , Tj ) - 100 \% \vert \qquad ( 20 )$$

$$S\_DQ = \frac{1}{o} {\sum }_{k = 1}^{o} SDQ ( Sk ) \qquad ( 21 )$$

Based on the above, substituting the calculated degrees of deviations in discharge energies of the battery string S1 in Table 7 into equation (20) gives 84.23%; substituting the calculated degrees of deviations in discharge energies of the battery string S2 in Table 7 into equation (20) gives 84.23%. Then, substituting these two calculated results into equation (21) gives 84.23%. Therefore, in this embodiment, the value of the string discharge balancing index (S_DQ) is 84.23%.

### The Third Calculation Method of Battery Discharge Balancing Index (B_DQ):

The following Table 8 and Table 9 are used to illustrate the third calculation method of the battery discharge balancing index (B_DQ). Please refer to FIG. 3, FIG. 1, Table 8 and Table 9. First, the control circuit 104 measures the discharge energy of each battery in each of n time slots to obtain n measured values of each battery, as shown in step S302. In this embodiment, n is 9. The measured values of the discharge energies of the batteries S1X1 to S1X3 in the battery string S1 are shown in Table 8, and the measured values of the discharge energies of the batteries S2X1 to S2X3

TABLE 8

| | | | | | degree of deviation in | |
|---|---|---|---|---|---|---|
| | discharge energy (W × Hr) | | | | discharge energy (%) | |
| time slot | S1X1 | S1X2 | S1X3 | BE_avg | BDq | BDQ |
| T1 (9:53 to 10:03) | 22.9391 | 22.9355 | 22.9147 | 22.9298 | 0.0131 | 0.06% |
| T2 (10:03 to 10:13) | 24.9179 | 24.9288 | 24.9085 | 24.9184 | 0.0101 | 0.04% |
| T3 (10:13 to 10:24) | 22.221 | 22.2372 | 22.2225 | 22.2269 | 0.0085 | 0.04% |
| T4 (10:24 to 10:34) | 22.8158 | 22.8322 | 22.8267 | 22.8249 | 0.0083 | 0.04% |
| T5 (10:34 to 10:44) | 22.8966 | 22.9212 | 22.9212 | 22.913 | 0.0142 | 0.06% |
| T6 (10:44 to 10:54) | 26.6955 | 26.7133 | 26.7571 | 26.7219 | 0.0317 | 0.12% |
| T7 (10:54 to 11:04) | 25.2504 | 24.9667 | 25.3866 | 25.2012 | 0.2142 | 0.85% |
| T8 (11:04 to 11:14) | 13.8313 | 11.8728 | 13.9469 | 13.217 | 1.1655 | 8.82% |
| T9 (11:14 to 11:24) | 9.28798 | 7.75202 | 9.45678 | 8.83226 | 0.9393 | 10.64% |

TABLE 9

| | | | | | degree of deviation in | |
|---|---|---|---|---|---|---|
| | discharge energy (W × Hr) | | | | discharge energy (%) | |
| time slot | S2X1 | S2X2 | S2X3 | BE_avg | BDq | BDQ |
| T1 (9:53 to 10:03) | 20.589 | 20.3885 | 20.6106 | 20.5294 | 0.1224 | 0.6% |
| T2 (10:03 to 10:13) | 22.4893 | 22.1641 | 22.5216 | 22.3917 | 0.1977 | 0.88% |
| T3 (10:13 to 10:24) | 20.3582 | 19.9772 | 20.389 | 20.2415 | 0.2293 | 1.13% |
| T4 (10:24 to 10:34) | 20.8582 | 20.3475 | 20.8961 | 20.7006 | 0.3063 | 1.48% |
| T5 (10:34 to 10:44) | 19.6696 | 18.9174 | 19.7043 | 19.4304 | 0.4446 | 2.29% |
| T6 (10:44 to 10:54) | 15.9315 | 14.4136 | 15.9627 | 15.4359 | 0.8855 | 5.74% |
| T7 (10:54 to 11:04) | 17.691 | 14.7504 | 17.7258 | 16.7224 | 1.7078 | 10.21% |
| T8 (11:04 to 11:14) | 30.4467 | 24.0023 | 30.5177 | 28.3222 | 3.7413 | 13.21% |
| T9 (11:14 to 11:24) | 17.7288 | 13.667 | 17.7799 | 16.3919 | 2.3599 | 14.4% |

in the battery string S2 are shown in Table 9. In Tables 8 and 9, the unit of discharge energy is the product of watts (W) and hours (Hr), where watts is the product of the battery voltage and the discharge current of the battery string.

Next, the control circuit 104 calculates an average discharge energy of the batteries in the same battery string in each time slot based on the following equation (1), as shown in step S304:

$$BE\_avg ( Sk , Tj ) = \frac{1}{m} {\sum }_{i = 1}^{m} BE ( SkXi , Tj ) \qquad ( 1 )$$

Since the content of equation (1) has been mentioned in the previous explanation, it will not be repeated here. The calculated values of the average discharge energies are shown in Tables 8 and 9.

After calculating an average discharge energy of the batteries in the same battery string in each time slot, the control circuit 104 accordingly calculates at least one degree of deviation in discharge energy of the batteries in the same battery string relative to the average discharge energy (as shown in step S304). In this embodiment, the control circuit 104 calculates the said at least one degree of deviation in discharge energy of the batteries in the same battery string relative to the average discharge energy based on the following equations (8) and (9):

$$BDq ( Sk , Tj ) = \sqrt{\frac{1}{m} {\sum }_{i = 1}^{m} {( BE ( SkXi , Tj ) - BE\_avg ( Sk , Tj ) )}^{2}} \qquad ( 8 )$$

$$BDQ ( Sk , Tj ) = \frac{BDq ( Sk , Tj )}{BE\_avg ( Sk , Tj )} \qquad ( 9 )$$

The calculated degrees of deviations in discharge energies are listed in column BDQ of Tables 8 and 9.

Then, the control circuit 104 calculates an average degree of deviation in discharge energy of the batteries in all time slots based on the calculated degrees of deviations in discharge energies, and serves the calculated average degree as the battery discharge balancing index (B_DQ), as shown in step S306. In this embodiment, the control circuit 104 calculates the average degree of deviation in discharge energy based on the following equation (10):

$$B\_DQ = 1 - \frac{1}{o * n} {\sum }_{k = 1}^{o} {\sum }_{j = 1}^{n} BDQ ( Sk , Tj ) ) \qquad ( 10 )$$

Based on the above, substituting the calculated degrees of deviations in discharge energies in Tables 8 and 9 into equation (10) gives 96.08%. Therefore, in this embodiment, the value of the battery discharge balancing index (B_DQ) is 96.08%.

### The Third Calculation Method of String Discharge Balancing Index (S_DQ):

The following Table 10 is used to illustrate the third calculation method of the string

TABLE 10

| | | | | degree of deviation in | |
|---|---|---|---|---|---|
| | discharge energy (W × Hr) | | | discharge energy (%) | |
| time slot | S1 | S2 | SE_avg | SDq | SDQ |
| T1 (9:53 to 10:03) | 68.7893 | 61.5881 | 65.1887 | 5.0920 | 7.81% |
| T2 (10:03 to 10:13) | 74.7552 | 67.175 | 70.9651 | 5.3600 | 7.55% |
| T3 (10:13 to 10:24) | 66.6807 | 60.7244 | 63.7025 | 4.2117 | 6.61% |
| T4 (10:24 to 10:34) | 68.4746 | 62.1018 | 65.2882 | 4.5062 | 6.90% |
| T5 (10:34 to 10:44) | 68.739 | 58.2913 | 63.5152 | 7.3876 | 11.63% |
| T6 (10:44 to 10:54) | 80.1658 | 46.3077 | 63.2368 | 23.9412 | 37.86% |
| T7 (10:54 to 11:04) | 75.6037 | 50.1671 | 62.8854 | 17.9863 | 28.60% |
| T8 (11:04 to 11:14) | 39.651 | 84.9667 | 62.3089 | 32.0430 | 51.43% |
| T9 (11:14 to 11:24) | 26.4968 | 49.1757 | 37.8363 | 16.0364 | 42.38% |

discharge balancing index (S_DQ). Please refer to FIG. 4, FIG. 1 and Table 10. First, the control circuit 104 measures the discharge energy of each battery string in each of n time slots to obtain n measured values of each battery string, as shown in step S402. The measured values of the discharge energies of the battery strings S1 and S2 are shown in Table 10. In Table 10, the unit of discharge energy is the product of watts (W) and hours (Hr), where watts is the product of the string voltage and the discharge current of the battery string.

Next, the control circuit 104 calculates an average discharge energy of the battery strings in each time slot based on the following equations (14) and (15), as shown in step S404:

$$SE ( Sk , Tj ) = {\sum }_{i = 1}^{m} BE ( SkXi , Tj ) \qquad ( 14 )$$

$$SE\_avg ( Tj ) = \frac{1}{o} {\sum }_{k = 1}^{o} SE ( Sk , Tj ) \qquad ( 15 )$$

The calculated values of the average discharge energies are shown in Table 10.

After calculating an average discharge energy of the battery strings in each time slot, the control circuit 104 accordingly calculates at least one degree of deviation in discharge energy of the battery strings relative to the average discharge energy (as shown in step S404). In this embodiment, the control circuit 104 calculates the said at least one degree of deviation in discharge energy of the battery strings relative to the average discharge energy based on the following equations (22) and (23):

$$SDq ( Tj ) = \sqrt{\frac{1}{o} {\sum }_{k = 1}^{o} {( SE ( Sk , Tj ) - SE\_avg ( Tj ) )}^{2}} \qquad ( 22 )$$

$$SDQ ( Tj ) = \frac{SDq ( Tj )}{SE\_avg ( Tj )} \qquad ( 23 )$$

The calculated degrees of deviations in discharge energies are listed in column SDQ of Table 10.

Then, the control circuit 104 calculates an average degree of deviation in discharge energy of the battery strings in all time slots based on the calculated degrees of deviations in discharge energies, and serves the calculated average degree as the string discharge balancing index (S_DQ), as shown in step S406. In this embodiment, the control circuit 104 calculates the average degree of deviation in discharge energy of the battery strings based on the following equation (24):

$$S \_ DQ = 1 - \frac{1}{n} {\sum }_{j = 1}^{n} SDQ ( Tj ) \qquad ( 24 )$$

Based on the above, substituting the calculated degrees of deviations in discharge energies in Table 10 into equation (24) gives 77.69%. Therefore, in this embodiment, the value of the string discharge balancing index (S_DQ) is 77.69%.

### The Fourth Calculation Method of Battery Discharge Balancing Index (B_DQ):

The following Table 11 and Table 12 are used to illustrate the fourth calculation method of the battery discharge balancing index (B_DQ). Please refer to FIG. 3, FIG. 1, Table 11 and Table 12. First, the control circuit 104 measures the discharge energy of each battery in each of n time slots to obtain n measured values of each battery, as shown in step S302. In this embodiment, n is 9. The measured values of the discharge energies of the batteries S1X1 to S1X3 in the battery string S1 are shown in Table 11, and the measured values of the discharge energies of the batteries S2X1 to S2X3 in the battery string S2 are shown in Table 12. In Tables 11 and 12, the unit of discharge energy is the

TABLE 11

| | | | | | degree of deviation in | |
|---|---|---|---|---|---|---|
| | discharge energy (W × Hr) | | | | discharge energy (%) | |
| time slot | S1X1 | S1X2 | S1X3 | BE_avg | BDq | BDQ |
| T1 (9:53 to 10:03) | 22.9391 | 22.9355 | 22.9147 | 22.9298 | 0.0100 | 0.04% |
| T2 (10:03 to 10:13) | 24.9179 | 24.9288 | 24.9085 | 24.9184 | 0.0069 | 0.03% |
| T3 (10:13 to 10:24) | 22.221 | 22.2372 | 22.2225 | 22.2269 | 0.0069 | 0.03% |
| T4 (10:24 to 10:34) | 22.8158 | 22.8322 | 22.8267 | 22.8249 | 0.0061 | 0.03% |
| T5 (10:34 to 10:44) | 22.8966 | 22.9212 | 22.9212 | 22.913 | 0.0109 | 0.05% |
| T6 (10:44 to 10:54) | 26.6955 | 26.7133 | 26.7571 | 26.7219 | 0.0234 | 0.09% |
| T7 (10:54 to 11:04) | 25.2504 | 24.9667 | 25.3866 | 25.2012 | 0.1564 | 0.62% |
| T8 (11:04 to 11:14) | 13.8313 | 11.8728 | 13.9469 | 13.217 | 0.8961 | 6.78% |
| T9 (11:14 to 11:24) | 9.28798 | 7.75202 | 9.45678 | 8.83226 | 0.7202 | 8.15% |

TABLE 12

| | | | | | degree of deviation in | |
|---|---|---|---|---|---|---|
| | discharge energy (W × Hr) | | | | discharge energy (%) | |
| time slot | S1X1 | S1X2 | S1X3 | BE_avg | BDq | BDQ |
| T1 (9:53 to 10:03) | 20.589 | 20.3885 | 20.6106 | 20.5294 | 0.0939 | 0.46% |
| T2 (10:03 to 10:13) | 22.4893 | 22.1641 | 22.5216 | 22.3917 | 0.1517 | 0.68% |
| T3 (10:13 to 10:24) | 20.3582 | 19.9772 | 20.389 | 20.2415 | 0.1762 | 0.87% |
| T4 (10:24 to 10:34) | 20.8582 | 20.3475 | 20.8961 | 20.7006 | 0.2354 | 1.14% |
| T5 (10:34 to 10:44) | 19.6696 | 18.9174 | 19.7043 | 19.4304 | 0.3420 | 1.76% |
| T6 (10:44 to 10:54) | 15.9315 | 14.4136 | 15.9627 | 15.4359 | 0.6816 | 4.42% |
| T7 (10:54 to 11:04) | 17.691 | 14.7504 | 17.7258 | 16.7224 | 1.3147 | 7.86% |
| T8 (11:04 to 11:14) | 30.4467 | 24.0023 | 30.5177 | 28.3222 | 2.8800 | 10.17% |
| T9 (11:14 to 11:24) | 17.7288 | 13.667 | 17.7799 | 16.3919 | 1.8166 | 11.08% |

product of watts (W) and hours (Hr), where watts is the product of the battery voltage and the discharge current of the battery string.

Next, the control circuit 104 calculates an average discharge energy of the batteries in the same battery string in each time slot based on the following equation (1), as shown in step S304:

$$BE \_ avg ( Sk , Tj ) = \frac{1}{m} {\sum }_{i = 1}^{m} BE ( SkXi , Tj ) \qquad ( 1 )$$

Since the content of equation (1) has been mentioned in the previous explanation, it will not be repeated here. The calculated values of the average discharge energies are shown in Tables 11 and 12.

After calculating an average discharge energy of the batteries in the same battery string in each time slot, the control circuit 104 accordingly calculates at least one degree of deviation in discharge energy of the batteries in the same battery string relative to the average discharge energy (as shown in step S304). In this embodiment, the control circuit 104 calculates the said at least one degree of deviation in discharge energy of the batteries in the same battery string relative to the average discharge energy based on the following equations (11) and (12):

$$BDq ( Sk , Tj ) = \frac{1}{m} {\sum }_{i = 1}^{m} \vert BE ( SkXi , Tj ) - BE \_ avg ( Sk , Tj ) \vert \qquad ( 11 )$$

$$BDQ ( Sk , Tj ) = \frac{BDq ( Sk , Tj )}{BE \_ avg ( Sk , Tj )} \qquad ( 12 )$$

The calculated degrees of deviations in discharge energies are listed in column BDQ of Tables 11 and 12.

Then, the control circuit 104 calculates an average degree of deviation in discharge energy of the batteries in all time slots based on the calculated degrees of deviations in discharge energies, and serves the calculated average degree as the battery discharge balancing index (B_DQ), as shown in step S306. In this embodiment, the control circuit 104 calculates the average degree of deviation in discharge energy based on the following equation (13):

$$B \_ DQ = 1 - \frac{1}{o * n} {\sum }_{k = 1}^{o} {\sum }_{j = 1}^{n} BDQ ( Sk , Tj ) \qquad ( 13 )$$

Based on the above, substituting the calculated degrees of deviations in discharge energies in Tables 11 and 12 into equation (13) gives 96.99%. Therefore, in this embodiment, the value of the battery discharge balancing index (B_DQ) is 96.99%.

### The Fourth Calculation Method of String Discharge Balancing Index (S_DQ):

The following Table 13 is used to illustrate the fourth calculation method of the string discharge balancing index (S_DQ). Please refer to FIG. 4, FIG. 1 and Table 13 First, the control circuit 104 measures the discharge energy of each battery string in each of n time slots to obtain n

TABLE 13

| | | | | degree of deviation in | |
|---|---|---|---|---|---|
| | discharge energy (W × Hr) | | | discharge energy (%) | |
| time slot | S1 | S2 | SE_avg | SDq | SDQ |
| T1 (9:53 to 10:03) | 68.7893 | 61.5881 | 65.1887 | 3.60 | 5.52% |
| T2 (10:03 to 10:13) | 74.7552 | 67.175 | 70.9651 | 3.79 | 5.34% |
| T3 (10:13 to 10:24) | 66.6807 | 60.7244 | 63.7025 | 2.98 | 4.68% |
| T4 (10:24 to 10:34) | 68.4746 | 62.1018 | 65.2882 | 3.19 | 4.88% |
| T5 (10:34 to 10:44) | 68.739 | 58.2913 | 63.5152 | 5.22 | 8.22% |
| T6 (10:44 to 10:54) | 80.1658 | 46.3077 | 63.2368 | 16.93 | 26.77% |
| T7 (10:54 to 11:04) | 75.6037 | 50.1671 | 62.8854 | 12.72 | 20.22% |
| T8 (11:04 to 11:14) | 39.651 | 84.9667 | 62.3089 | 22.66 | 36.36% |
| T9 (11:14 to 11:24) | 26.4968 | 49.1757 | 37.8363 | 11.34 | 29.97% |

measured values of each battery string, as shown in step S402. The measured values of the discharge energies of the battery strings S1 and S2 are shown in Table 13. In Table 13, the unit of discharge energy is the product of watts (W) and hours (Hr), where watts is the product of the string voltage and the discharge current of the battery string.

Next, the control circuit 104 calculates an average discharge energy of the battery strings in each time slot based on the following equations (14) and (15), as shown in step S404:

$$SE ( Sk , Tj ) = {\sum }_{i = 1}^{m} BE ( SkXi , Tj ) \qquad ( 14 )$$

$$SE \_ avg ( Tj ) = \frac{1}{o} {\sum }_{k = 1}^{o} SE ( Sk , Tj ) \qquad ( 15 )$$

The calculated values of the average discharge energies are shown in Table 13.

After calculating an average discharge energy of the battery strings in each time slot, the control circuit 104 accordingly calculates at least one degree of deviation in discharge energy of the battery strings relative to the average discharge energy (as shown in step S404). In this embodiment, the control circuit 104 calculates the said at least one degree of deviation in discharge energy of the battery strings relative to the average discharge energy based on the following equations (25) and (26):

$$SDq ( Tj ) = \frac{1}{o} {\sum }_{k = 1}^{o} \vert SE ( Sk , Tj ) - SE \_ avg ( Tj ) \vert \qquad ( 25 )$$

$$SDQ ( Tj ) = \frac{SDq ( Tj )}{SE \_ avg ( Tj )} \qquad ( 26 )$$

The calculated degrees of deviations in discharge energies are listed in column SDQ of Table 13.

Then, the control circuit 104 calculates an average degree of deviation in discharge energy of the battery strings in all time slots based on the calculated degrees of deviations in discharge energies, and serves the calculated average degree as the string discharge balancing index (S_DQ), as shown in step S406. In this embodiment, the control circuit 104 calculates the average degree of deviation in discharge energy of the battery strings based on the following equation (27):

$$S \_ DQ = 1 - \frac{1}{n} {\sum }_{j = 1}^{n} SDQ ( Tj ) \qquad ( 27 )$$

Based on the above, substituting the calculated degrees of deviations in discharge energies in Table 13 into equation (27) gives 84.23%. Therefore, in this embodiment, the value of the string discharge balancing index (S_DQ) is 84.23%.

In summary, the present invention allows management personnel to quickly determine whether the entire battery system has a long-term failure risk, and management personnel can do so without extensive expertise in battery systems.

While the disclosure has been described by way of example and in terms of the preferred embodiments, it is to be understood that the disclosure is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A method for intuitive quantification of battery discharge balancing quality, applicable to at least one battery string, each battery string consisting of m batteries connected in series, where m is a natural number, the method comprising the following steps:
calculating a battery discharge balancing index (B_DQ), comprising the following steps:
measuring the discharge energy of each battery in each of n time slots to obtain n measured values of each battery, where n is a natural number;
calculating an average discharge energy of the batteries in the same battery string in each time slot, and accordingly calculating at least one degree of deviation in discharge energy of the batteries in the same battery string relative to the average discharge energy; and
calculating an average degree of deviation in discharge energy of the batteries in all time slots based on the calculated degrees of deviations in discharge energies, and serving the calculated average degree as the battery discharge balancing index (B_DQ); and
determine whether the number of the battery strings is 1; if not, calculating a string discharge balancing index (S_DQ); if so, assigning a value of 100% to the string discharge balancing index (S_DQ).

2. The method as claimed in claim 1, wherein the average discharge energy is calculated based on the following equation (1):
$$BE \_ avg ( Sk , Tj ) = \frac{1}{m} {\sum }_{i = 1}^{m} BE ( SkXi , Tj ) \qquad ( 1 )$$
where Sk in (SkXi, Tj) represents the kth battery string, Xi represents the ith battery, Tj represents the jth time slot, BE(SkXi,Tj) represents the discharge energy of the battery SkXi in the jth time slot, where the value of k is 1 to o, the value of i is 1 to m, and the value of j is 1 to n, where o is a natural number.

3. The method as claimed in claim 2, wherein the said at least one degree of deviation in discharge energy of the batteries in the same battery string relative to the average discharge energy is calculated based on the following equation (2):
$$BDq ( Xi , Tj ) = \frac{BE ( SkXi , Tj ) - BE \_ avg ( Sk , Tj )}{BE \_ avg ( Sk , Tj )} \qquad ( 2 )$$

4. The method as claimed in claim 3, wherein the average degree of deviation in discharge energy is calculated based on the following equations (3) and (4):
$$BDQ ( Xi ) = 1 - \frac{1}{n} {\sum }_{j = 1}^{n} \vert BDq ( SkXi , Tj ) \vert \qquad ( 3 )$$
$$B \_ DQ = \frac{1}{o * m} {\sum }_{k = 1}^{o} {\sum }_{i = 1}^{m} BDQ ( SkXi ) \qquad ( 4 )$$

5. The method as claimed in claim 2, wherein the said at least one degree of deviation in discharge energy of the batteries in the same battery string relative to the average discharge energy is calculated based on the following equation (5):
$$BDq ( Xi , Tj ) = \frac{BE ( SkXi , Tj )}{BE \_ avg ( Sk , Tj )} \qquad ( 5 )$$

6. The method as claimed in claim 5, wherein the average degree of deviation in discharge energy is calculated based on the following equations (6) and (7):
$$BDQ ( Xi ) = 1 - \frac{1}{n} {\sum }_{j = 1}^{n} \vert BDq ( SkXi , Tj ) - 100 \% \vert \qquad ( 6 )$$
$$B \_ DQ = \frac{1}{o * m} {\sum }_{k = 1}^{o} {\sum }_{i = 1}^{m} BDQ ( SkXi ) \qquad ( 7 )$$

7. The method as claimed in claim 2, wherein the said at least one degree of deviation in discharge energy of the batteries in the same battery string relative to the average discharge energy is calculated based on the following equations (8) and (9):
$$BDq ( Sk , Tj ) = \sqrt{\frac{1}{m} {\sum }_{i = 1}^{m} {( BE ( SkXi , Tj ) - BE \_ avg ( Sk , Tj ) )}^{2}} \qquad ( 8 )$$
$$BDQ ( Sk , Tj ) = \frac{BDq ( Sk , Tj )}{BE \_ avg ( Sk , Tj )} \qquad ( 9 )$$

8. The method as claimed in claim 7, wherein the average degree of deviation in discharge energy is calculated based on the following equation (10):
$$B \_ DQ = 1 - \frac{1}{o * n} {\sum }_{k = 1}^{o} {\sum }_{j = 1}^{n} BDQ ( Sk , Tj ) ) \qquad ( 10 )$$

9. The method as claimed in claim 2, wherein the said at least one degree of deviation in discharge energy of the batteries in the same battery string relative to the average discharge energy is calculated based on the following equations (11) and (12):
$$BDq ( Sk , Tj ) = \frac{1}{m} {\sum }_{i = 1}^{m} \vert BE ( SkXi , Tj ) - BE \_ avg ( Sk , Tj ) \vert \qquad ( 11 )$$
$$BDQ ( Sk , Tj ) = \frac{BDq ( Sk , Tj )}{BE \_ avg ( Sk , Tj )} \qquad ( 12 )$$

10. The method as claimed in claim 9, wherein the average degree of deviation in discharge energy is calculated based on the following equation (13):
$$B \_ DQ = 1 - \frac{1}{o * n} {\sum }_{k = 1}^{o} {\sum }_{j = 1}^{n} B D Q ( Sk , Tj ) \qquad ( 13 )$$

11. The method as claimed in claim 2, wherein the steps for calculating the string discharge balancing index (S_DQ) comprise:
measuring the discharge energy of each battery string in each of n time slots to obtain n measured values of each battery string;
calculating an average discharge energy of the battery strings in each time slot, and accordingly calculating at least one degree of deviation in discharge energy of the battery strings relative to the average discharge energy; and
calculating an average degree of deviation in discharge energy of the battery strings in all time slots based on the calculated degrees of deviations in discharge energies, and serving the calculated average degree as the string discharge balancing index (S_DQ).

12. The method as claimed in claim 11, wherein the average discharge energy of the battery strings is calculated based on the following equations (14) and (15):
$$SE ( Sk , Tj ) = {\sum }_{i = 1}^{m} B E ( S k Xi , Tj ) \qquad ( 14 )$$
$$SE \_avg ( Tj ) = \frac{1}{o} {\sum }_{k = 1}^{o} SE ( Sk , Tj ) \qquad ( 15 )$$

13. The method as claimed in claim 12, wherein the said at least one degree of deviation in discharge energy of the battery strings relative to the average discharge energy is calculated based on the following equation (16):
$$S D q ( Sk , Tj ) = \frac{SE ( Sk , Tj ) - SE \_avg ( Tj )}{SE \_avg ( Tj )} \qquad ( 16 )$$

14. The method as claimed in claim 13, wherein the average degree of deviation in discharge energy of the battery strings is calculated based on the following equations (17) and (18):
$$S D Q ( S k ) = 1 - \frac{1}{n} {\sum }_{j = 1}^{n} \vert SDq ( S k , Tj ) \vert \qquad ( 17 )$$
$$S \_ DQ = \frac{1}{o} {\sum }_{k = 1}^{o} S D Q ( S k ) \qquad ( 18 )$$

15. The method as claimed in claim 12, wherein the said at least one degree of deviation in discharge energy of the battery strings relative to the average discharge energy is calculated based on the following equation (19):
$$S D q ( Sk , Tj ) = \frac{S E ( Sk , Tj )}{SE \_avg ( Tj )} \qquad ( 19 )$$

16. The method as claimed in claim 15, wherein the average degree of deviation in discharge energy of the battery strings is calculated based on the following equations (20) and (21):
$$S D Q ( S k ) = 1 - \frac{1}{n} {\sum }_{j = 1}^{n} \vert SDq ( Sk , T j ) - 100 \% \vert \qquad ( 20 )$$
$$S \_ DQ = \frac{1}{o} {\sum }_{k = 1}^{o} S D Q ( S k ) \qquad ( 21 )$$

17. The method as claimed in claim 12, wherein the said at least one degree of deviation in discharge energy of the battery strings relative to the average discharge energy is calculated based on the following equations (22) and (23):
$$S D q ( T j ) = \sqrt{\frac{1}{o} {\sum }_{k = 1}^{o} {( S E ( S k , T j ) - SE \_avg ( Tj ) )}^{2}} \qquad ( 22 )$$
$$SDQ ( T j ) = \frac{S Dq ( Tj )}{SE \_avg ( Tj )} \qquad ( 23 )$$

18. The method as claimed in claim 17, wherein the average degree of deviation in discharge energy of the battery strings is calculated based on the following equation (24):
$$S \_ DQ = 1 - \frac{1}{n} {\sum }_{j = i}^{n} S DQ ( Tj ) \qquad ( 24 )$$

19. The method as claimed in claim 12, wherein the said at least one degree of deviation in discharge energy of the battery strings relative to the average discharge energy is calculated based on the following equations (25) and (26):
$$S D q ( T j ) = \frac{1}{o} {\sum }_{k = 1}^{o} \vert SE ( Sk , Tj ) - SE \_avg ( Tj ) \vert \qquad ( 25 )$$
$$SDQ ( T j ) = \frac{S D q ( T j )}{SE \_avg ( Tj )} \qquad ( 26 )$$

20. The method as claimed in claim 19, wherein the average degree of deviation in discharge energy of the battery strings is calculated based on the following equation (27):
$$S \_ DQ = 1 - \frac{1}{n} {\sum }_{j = 1}^{n} S DQ ( Tj ) \qquad ( 27 )$$

21. The method as claimed in claim 1, further comprising:
presenting the battery discharge balancing index (B_DQ) and the string discharge balancing index (S_DQ).

22. The method as claimed in claim 21, further comprising presenting the battery discharge balancing index (B_DQ) and the string discharge balancing index (S_DQ) in at least one of visual or audio forms.

23. The method as claimed in claim 1, further comprising:
generating and sending a prompt message based on the battery discharge balancing index (B_DQ) and the string discharge balancing index (S_DQ).

24. The method as claimed in claim 23, wherein the prompt message comprises at least one of a visual message or an audio message.

25. A battery management system, comprising:
at least one battery string, each battery string consisting of m batteries connected in series, where m is a natural number; and
a control circuit, electrically coupled to two terminals of each battery, the control circuit being used to calculate a battery discharge balancing index (B_DQ) and to determine whether the number of battery strings is 1, the control circuit calculating a string discharge balancing index (S_DQ) when the number of the battery strings is not 1, and assigning a value of 100% to the string discharge balancing index (S_DQ) when the number of the battery strings is 1, wherein the steps of the control circuit for calculating the battery discharge balancing index (B_DQ) comprise:
measuring the discharge energy of each battery in each of n time slots to obtain n measured values of each battery, where n is a natural number;
calculating an average discharge energy of the batteries in the same battery string in each time slot, and accordingly calculating at least one degree of deviation in discharge energy of the batteries in the same battery string relative to the average discharge energy; and
calculating an average degree of deviation in discharge energy of the batteries in all time slots based on the calculated degrees of deviations in discharge energies, and serving the calculated average degree as the battery discharge balancing index (B_DQ).

26. The battery management system as claimed in claim 25, wherein the control circuit calculates the average discharge energy based on the following equation (1):
$$BE \_avg ( Sk , Tj ) = \frac{1}{m} {\sum }_{i = 1}^{m} BE ( SkXi , Tj ) \qquad ( 1 )$$
where Sk in (SkXi, Tj) represents the kth battery string, Xi represents the ith battery, Tj represents the jth time slot, BE(SkXi,Tj) represents the discharge energy of the battery SkXi in the jth time slot, where the value of k is 1 to o, the value of i is 1 to m, and the value of j is 1 to n, where o is a natural number.

27. The battery management system as claimed in claim 26, wherein the control circuit calculates the said at least one degree of deviation in discharge energy of the batteries in the same battery string relative to the average discharge energy based on the following equation (2):
$$B D q ( Xi , Tj ) = \frac{B E ( S k Xi , Tj ) - BE \_avg ( Sk , Tj )}{BE \_avg ( Sk , Tj )} \qquad ( 2 )$$

28. The battery management system as claimed in claim 27, wherein the control circuit calculates the average degree of deviation in discharge energy based on the following equations (3) and (4):
$$B D Q ( X i ) = 1 - \frac{1}{n} {\sum }_{j = 1}^{n} \vert BDq ( S k Xi , Tj ) \vert \qquad ( 3 )$$
$$B \_ DQ = \frac{1}{o * m} {\sum }_{k = 1}^{o} {\sum }_{i = 1}^{m} B D Q ( S k X i ) \qquad ( 4 )$$

29. The battery management system as claimed in claim 26, wherein the control circuit calculates the said at least one degree of deviation in discharge energy of the batteries in the same battery string relative to the average discharge energy based on the following equation (5):
$$B D q ( Xi , Tj ) = \frac{B E ( S k Xi , Tj )}{BE \_avg ( Sk , Tj )} \qquad ( 5 )$$

30. The battery management system as claimed in claim 29, wherein the control circuit calculates the average degree of deviation in discharge energy based on the following equations (6) and (7):
$$BDQ ( X i ) = 1 - \frac{1}{n} {\sum }_{j = 1}^{n} \vert BDq ( SkXi , Tj ) - 100 \% \vert \qquad ( 6 )$$
$$B\_DQ = \frac{1}{o * m} {\sum }_{k = 1}^{o} {\sum }_{i = 1}^{m} BDQ ( S k X i ) \qquad ( 7 )$$

31. The battery management system as claimed in claim 26, wherein the control circuit calculates the said at least one degree of deviation in discharge energy of the batteries in the same battery string relative to the average discharge energy based on the following equations (8) and (9):
$$BDq ( Sk , Tj ) = \sqrt{\frac{1}{m} {\sum }_{i = 1}^{m} {( B E ( SkXi , Tj ) - BE\_avg ( S k , Tj ) )}^{2}} \qquad ( 8 )$$
$$BDQ ( Sk , Tj ) = \frac{B D q ( Sk , Tj )}{BE\_avg ( Sk , Tj )} \qquad ( 9 )$$

32. The battery management system as claimed in claim 31, wherein the control circuit calculates the average degree of deviation in discharge energy based on the following equation (10):
$$B\_DQ = 1 - \frac{1}{o * n} {\sum }_{k = 1}^{o} {\sum }_{j = 1}^{n} BDQ ( Sk , Tj ) ) \qquad ( 10 )$$

33. The battery management system as claimed in claim 26, wherein the control circuit calculates the said at least one degree of deviation in discharge energy of the batteries in the same battery string relative to the average discharge energy based on the following equations (11) and (12):
$$BDq ( Sk , Tj ) = \frac{1}{m} {\sum }_{i = 1}^{m} \vert BE ( S k Xi , Tj ) - BE\_avg ( Sk , Tj ) \vert \qquad ( 11 )$$
$$BDQ ( Sk , Tj ) = \frac{B D q ( Sk , Tj )}{BE\_avg ( Sk , Tj )} \qquad ( 12 )$$

34. The battery management system as claimed in claim 33, wherein the control circuit calculates the average degree of deviation in discharge energy based on the following equation (13):
$${B}_{DQ} = 1 - \frac{1}{o * n} {\sum }_{k = 1}^{o} {\sum }_{j = 1}^{n} BDQ ( S k , Tj ) \qquad ( 13 )$$

35. The battery management system as claimed in claim 26, wherein the steps for the control circuit to calculate the string discharge balancing index (S_DQ) comprise:
measuring the discharge energy of each battery string in each of n time slots to obtain n measured values of each battery string;
calculating an average discharge energy of the battery strings in each time slot, and accordingly calculating at least one degree of deviation in discharge energy of the battery strings relative to the average discharge energy; and
calculating an average degree of deviation in discharge energy of the battery strings in all time slots based on the calculated degrees of deviations in discharge energies, and serving the calculated average degree as the string discharge balancing index (S_DQ).

36. The battery management system as claimed in claim 35, wherein the control circuit calculates the average discharge energy of the battery strings based on the following equations (14) and (15):
$$SE ( Sk , Tj ) = {\sum }_{i = 1}^{m} BE ( S k Xi , Tj ) \qquad ( 14 )$$
$$SE\_avg ( Tj ) = \frac{1}{o} {\sum }_{k = 1}^{o} SE ( Sk , Tj ) \qquad ( 15 )$$

37. The battery management system as claimed in claim 36, wherein the control circuit calculates the said at least one degree of deviation in discharge energy of the battery strings relative to the average discharge energy based on the following equation (16):
$$S D q ( Sk , Tj ) = \frac{S E ( Sk , Tj ) - SE\_avg ( Tj )}{SE\_avg ( T j )} \qquad ( 16 )$$

38. The battery management system as claimed in claim 37, wherein the control circuit calculates the average degree of deviation in discharge energy of the battery strings based on the following equations (17) and (18):
$$SDQ ( S k ) = 1 - \frac{1}{n} {\sum }_{j = 1}^{n} \vert SDq ( S k , Tj ) \vert \qquad ( 17 )$$
$$S\_DQ = \frac{1}{o} {\sum }_{k = 1}^{o} SDQ ( S k ) \qquad ( 18 )$$

39. The battery management system as claimed in claim 36, wherein the control circuit calculates the said at least one degree of deviation in discharge energy of the battery strings relative to the average discharge energy based on the following equation (19):
$$S D q ( Sk , Tj ) = \frac{S E ( Sk , Tj )}{SE\_avg ( T j )} \qquad ( 19 )$$

40. The battery management system as claimed in claim 39, wherein the control circuit calculates the average degree of deviation in discharge energy of the battery strings based on the following equations (20) and (21):
$$SDQ ( S k ) = 1 - \frac{1}{n} {\sum }_{j = 1}^{n} \vert SDq ( Sk , Tj ) - 100 \% \vert \qquad ( 20 )$$
$$S\_DQ = \frac{1}{o} {\sum }_{k = 1}^{o} SDQ ( S k ) \qquad ( 21 )$$

41. The battery management system as claimed in claim 36, wherein the control circuit calculates the said at least one degree of deviation in discharge energy of the battery strings relative to the average discharge energy based on the following equations (22) and (23):
$$SDq ( T j ) = \sqrt{\frac{1}{o} {\sum }_{k = 1}^{o} {( SE ( S k , Tj ) - SE\_avg ( Tj ) )}^{2}} \qquad ( 22 )$$
$$SDQ ( Tj ) = \frac{S D q ( Tj )}{SE\_avg ( Tj )} \qquad ( 23 )$$

42. The battery management system as claimed in claim 41, wherein the control circuit calculates the average degree of deviation in discharge energy of the battery strings based on the following equation (24):
$$S\_DQ = 1 - \frac{1}{n} {\sum }_{j = 1}^{n} SDQ ( Tj ) \qquad ( 24 )$$

43. The battery management system as claimed in claim 36, wherein the control circuit calculates the said at least one degree of deviation in discharge energy of the battery strings relative to the average discharge energy based on the following equations (25) and (26):
$$SDq ( T j ) = \frac{1}{o} {\sum }_{k = 1}^{o} \vert SE ( Sk , Tj ) - SE\_avg ( Tj ) \vert \qquad ( 25 )$$
$$SDQ ( Tj ) = \frac{S D q ( Tj )}{SE\_avg ( Tj )} \qquad ( 26 )$$

44. The battery management system as claimed in claim 43, wherein the control circuit calculates the average degree of deviation in discharge energy of the battery strings based on the following equation (27):
$$S\_DQ = 1 - \frac{1}{n} {\sum }_{j = 1}^{n} SDQ ( Tj ) \qquad ( 27 )$$

45. The battery management system as claimed in claim 25, further comprises a message prompt device, the message prompt device is electrically coupled to the control circuit and is used to present the battery discharge balance indicator (B_DQ) and the string discharge balancing index (S_DQ).

46. The battery management system as claimed in claim 45, wherein the message prompt device comprises at least one of a display unit or an audio unit to present the battery discharge balancing index (B_DQ) and the string discharge balancing index (S_DQ) in at least one of visual or audio forms.

47. The battery management system as claimed in claim 45, wherein the control circuit further generates a prompt message based on the battery discharge balancing index (B_DQ) and the string discharge balancing index (S_DQ), and sends the prompt message through the message prompt device.

48. The battery management system as claimed in claim 47, wherein the prompt message comprises at least one of a visual message or an audio message.
